(19) United States
(12) Patent Application Publication
(10) Pub. No.: US 2014/0017845 A1
(43) Pub. Date: Jan. 16, 2014

(54) Method Of Forming A Photovoltaic Cell Module With A Cell Press

(71) Applicants: Donnie Juen, Sanford, MI (US); Barry Ketola, Freeland, MI (US); Richard Sibbick, Cardiff (GB)

(72) Inventors: Donnie Juen, Sanford, MI (US); Barry Ketola, Freeland, MI (US); Richard Sibbick, Cardiff (GB)

(73) Assignee: Dow Corning Corporation, Midland, MI (US)

(21) Appl. No.: 14/008,046

(22) PCT Filed: Mar. 28, 2012
(86) PCT No.: PCT/US12/30924

§ 371 Date: Sep. 27, 2013

Related U.S. Application Data
(60) Provisional application No. 61/470,115, filed on Mar. 31, 2011.

(51) Int. Cl. H01L 31/048; H01L 21/02

(52) U.S. Cl. CPC H01L 31/048; H01L 21/02
USPC 438/66; 425/406

(57) ABSTRACT

A photovoltaic cell module is formed with the use of a cell press. The cell press has a longitudinal axis, two surfaces disposed opposite each other along the longitudinal axis, and a fluidic mechanism for moving at least one of the two surfaces towards the other of the two surfaces along the longitudinal axis. A method includes the step of disposing a substrate, photovoltaic cell, tie layer or precursor thereof, and superstrate between the two surfaces and spaced from one of the two surfaces. The method also includes the step of moving at least one of the two surfaces along the longitudinal axis towards the other of the two surfaces using the fluidic mechanism to compress the substrate, photovoltaic cell, tie layer or precursor thereof, and superstrate and form the photovoltaic cell module. The precursor has a viscosity of less than about 1,500 cPs measured at 25° C. before curing.

This disclosure generally relates to a method of forming a photovoltaic cell module with a cell press. The cell press has two surfaces disposed opposite each other and a fluidic mechanism for moving at least one of the two surfaces towards the other of the two surfaces.

Photovoltaic cells are included in photovoltaic cell modules (modules) that typically include tie layers, substrates, superstrates, and/or additional materials or layers that provide strength and stability. In many applications, the tie layers are used to encapsulate the photovoltaic cells to provide additional protection from environmental factors such as wind and rain. Some modules include glass substrates bonded to glass superstrates using thick tie layers. These types of modules are usually made using processes that are slow and inefficient due to a need to control the dispersion of the tie layers and to minimize leakage of the tie layers from the substrates and superstrates to reduce waste. In addition, careful consideration must be given to the pressures and temperatures used to form such modules due to a potential for shattering and breakage. Other types of modules are formed using copious amounts of tie layers that are pushed out from between the substrate and the superstrate and are discarded. In both types of modules, it is difficult to control a thickness of the tie layers because the tie layers can flow across the substrates and superstrates in inconsistent patterns. In addition, it is difficult to control the formation of unsightly air bubbles in the tie layer. As such, methods of forming both types of modules result in increased expense, increased processing times, and increased processing complexity. In some cases, these methods are entirely ineffective. All of these disadvantages result in increased cost for the end purchaser.

Modules are typically formed in bulk using mechanical weights, nip/pinch rollers, autoclaves, or with vacuum lamination. In many production methods, the photovoltaic cell, tie layer, substrate, and superstrate are pressed together to ensure contact and encapsulation. However, when the photovoltaic cell contacts the tie layer, air bubbles can become trapped in the tie layer and/or between the photovoltaic cell and the tie layer. These air bubbles are disadvantageous and make the module susceptible to the environment, decrease the mechanical strength of the module, and reduce the light absorbing capability of the module.

By applying pressure to the photovoltaic cell using mechanical weight and rollers, some of the air bubbles can be squeezed out. However, to remove any considerable amount of air bubbles, the pressure must either be very high or must be applied for a substantial amount of time while the air bubbles slowly flow out. As described above, use of high pressure increases the likelihood that the modules will shatter or break which makes the slower (and lower pressure) process more commercially desirable. Vacuum can also be used but tends to be costly and also time consuming. The time consumed by slower processes is not cost effective or efficient. This slower process greatly increases cycle times thereby reducing the number of modules that can be assembled in a given amount of time. Accordingly, there remains an opportunity to develop an improved method of forming modules.

### SUMMARY OF THE DISCLOSURE

This disclosure provides a method of forming a photovoltaic cell module including a substrate, a photovoltaic cell disposed on the substrate, a tie layer disposed on the photovoltaic cell, and a superstrate disposed on the tie layer. The photovoltaic cell module is formed with the use of a cell press having a longitudinal axis, two surfaces disposed opposite each other along the longitudinal axis, and a fluidic mechanism for moving at least one of the two surfaces towards the other of the two surfaces along the longitudinal axis. The method includes the step of disposing the substrate, photovoltaic cell, tie layer or precursor thereof, and superstrate between the two surfaces and spaced from one of the two surfaces. The method also includes the step of moving at least one of the two surfaces along the longitudinal axis towards the other of the two surfaces using the fluidic mechanism to compress the substrate, photovoltaic cell, tie layer or precursor thereof, and superstrate and form the photovoltaic cell module. The precursor of the tie layer has a viscosity of less than about 1,500 cPs measured at 25° C.

### DESCRIPTION OF THE FIGURES

FIG. 1A is a side schematic view of one embodiment of the cell press wherein the cell press includes an inflatable bladder and the inflatable bladder inflates to exert force downwards on the photovoltaic cell module during formation;

FIG. 1B is a side schematic view of another embodiment of the cell press wherein the cell press includes an inflatable bladder and the inflatable bladder inflates to exert force upwards on the photovoltaic cell module during formation;

FIG. 1C is a process schematic illustrating various stages of inflation (from left to right) of the inflatable bladder of FIG. 1A to exert force downwards on the photovoltaic cell module during formation;

FIG. 2A is a side schematic view of still another embodiment of the cell press wherein the cell press includes two platen and an inflatable bladder sandwiched therebetween and the inflatable bladder inflates and exerts force downwards on one of the platen and on the photovoltaic cell module during formation;

FIG. 2B is a side schematic view of yet another embodiment of the cell press wherein the cell press includes two platen and an inflatable bladder sandwiched therebetween and the inflatable bladder inflates and exerts force upwards on one of the platen and on the photovoltaic cell module during formation;

FIG. 2C is a side schematic view of an additional embodiment of the cell press of FIG. 2B further including two additional platen and an additional inflatable bladder sandwiched between the two additional platen wherein both inflatable bladders inflate and exert force both upwards and downwards on the platen and on the photovoltaic cell module during formation, respectively;

FIG. 2D is a process schematic illustrating various stages of inflation (from left to right) of the inflatable bladder of FIG. 2A to exert force downwards on one of the platen and on the photovoltaic cell module during formation;

FIG. 3A is a side schematic view of a further embodiment of the cell press wherein the cell press includes two platen and one of the platen exerts force upwards on the photovoltaic cell module during formation;

FIG. 3B is a side schematic view of a still further embodiment of the cell press wherein the cell press includes two platen and one of the platen exerts force downwards on the photovoltaic cell module during formation;

FIG. 3C is a side schematic view of another embodiment of the cell press wherein the cell press includes two platen and one of the platen exerts force downwards while the other of the platen exerts force upwards, simultaneously, on the photovoltaic cell module during formation;

FIG. 3D is a process schematic illustrating the operation of the cell press of FIG. 3A wherein one of the platen exerts force upwards on the photovoltaic cell module during formation;

FIG. 4A is a side cross-sectional view of a further embodiment of the cell press with a table of the cell press and a shuttle plate supporting a plurality of photovoltaic cells and with a plate of the cell press in retracted position spaced from the photovoltaic cells and disposed to exert downward force on the modules during formation;

FIG. 4B is a side cross-sectional view of another embodiment of the cell press wherein the table and plate are disposed to exert both downward and upward force on the modules during formation, respectively;

FIG. 5 is a side cross-sectional view of still another embodiment of the cell press wherein an inflatable bladder is disposed between two platen to exert downward force on the modules during formation;

FIG. 6 is a side cross-sectional view of another embodiment of the cell press wherein an inflatable bladder is disposed to exert downward force on the modules during formation;

FIG. 7A is a side view of one embodiment of an insert that may be utilized in the cell press wherein the insert includes discrete layers;

FIG. 7B is a side view of a second embodiment of the insert that may be utilized in the cell press wherein the insert includes discrete layers;

FIG. 7C is a side view of a third embodiment of the insert that may be utilized in the cell press wherein the insert includes discrete layers;

FIG. 7D is a side view of a fourth embodiment of the insert that may be utilized in the cell press wherein the insert includes discrete layers;

FIG. 7E is a side schematic view of one embodiment of the insert that may be utilized in the cell press wherein force is applied to the first outermost layer and distributed from the center of the insert, through the intermediate layer, and out towards the periphery of the second outermost layer;

FIG. 7F is a side view of an embodiment of the insert wherein the insert is integral and does not include discrete layers;

FIG. 8A is a side cross-sectional view of the cell press of FIG. 4A including an embodiment of the insert that is disposed on a plate;

FIG. 8B is a side cross-sectional view of the cell press of FIG. 4A including an embodiment of the insert that is disposed in contact with the modules;

FIG. 9A is a side cross-sectional view of the cell press of FIG. 5 including an embodiment of the insert that is disposed on a platen;

FIG. 9B is a side cross-sectional view of the cell press of FIG. 5 including an embodiment of the insert that is disposed in contact with the modules;

FIG. 10 is a side cross-sectional view of one embodiment of the photovoltaic cell module including a substrate, a photovoltaic cell disposed on, and in direct contact with, the substrate, a tie layer disposed on, and in direct contact with, the photovoltaic cell, and a superstrate disposed on, and in direct contact with, the tie layer.

### DETAILED DESCRIPTION OF THE DISCLOSURE

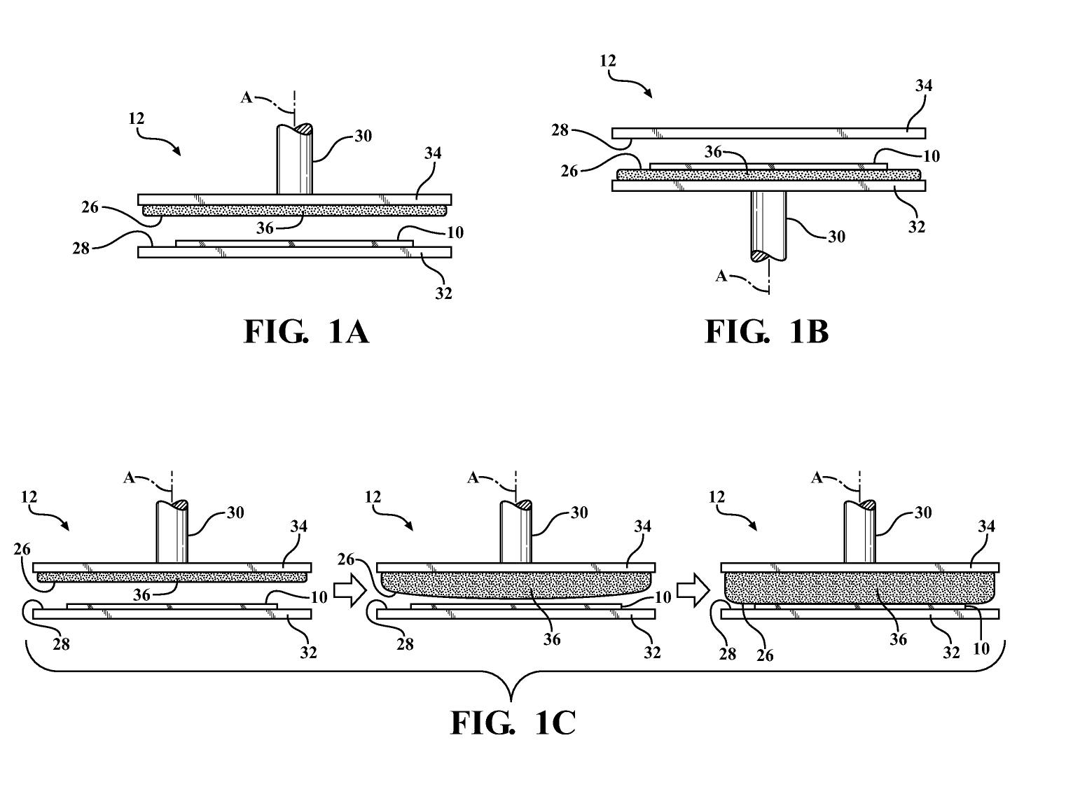

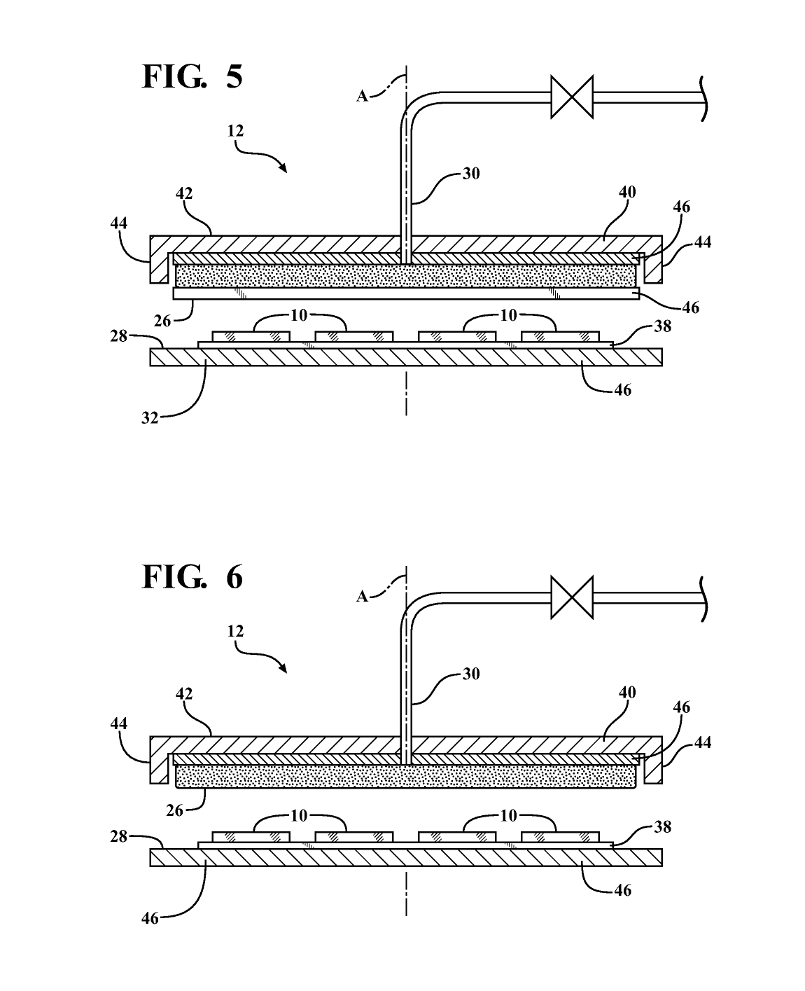

This disclosure provides a method of forming a photovoltaic cell module 10 (hereinafter referred to as “module”) using a cell press 12, as shown in the Figures. The module 10, after formation, includes a substrate 14, a photovoltaic cell 16 disposed on the substrate 14, a tie layer 18, disposed on the photovoltaic cell 16, and a superstrate 20 disposed on the tie layer 18. The terminology “disposed on” may describe any one of the aforementioned components (14-20) disposed on and in direct contact with any of the other components (14-20). Alternatively, any one of the components (14-20) may be disposed on, but spaced apart from, any of the other components (14-20) such that there is no direct contact therebetween. For example, the photovoltaic cell 16 may be disposed on and in direct contact with the substrate 14 or may be disposed on, and spaced apart from, the substrate 14 with another component or layer disposed therebetween. In one embodiment, the photovoltaic cell 16 is in direct contact with both the substrate 14 and the tie layer 18. The photovoltaic cell 16 may alternatively be sandwiched between the tie layer 18 and a second tie layer, as described in greater detail below. In various embodiments, the module 10 is as described in WO 2010/051355, which is expressly incorporated herein by reference in its entirety and further cited below. In one embodiment, the photovoltaic cell 16 is disposed on, and in direct contact with, the substrate 14, the tie layer 18 is disposed on, and in direct contact with, the photovoltaic cell 16, and the superstrate 20 is disposed on, and in direct contact with, the tie layer 18, as shown in FIG. 10. Alternatively, a second tie layer (described in greater detail below) is disposed on and in direct contact with the substrate 14, the photovoltaic cell 16 is disposed on, and in direct contact with, the second tie layer, the tie layer 18 is disposed on, and in direct contact with, the photovoltaic cell 16, and the superstrate 20 is disposed on, and in direct contact with, the tie layer 18. In still another embodiment, the tie layer 18 is disposed on and in direct contact with the substrate 14, the photovoltaic cell 16 is disposed on and in direct contact with the tie layer 18, and the superstrate 20 is disposed on and in direct contact with the photovoltaic cell 16. In this embodiment, the photovoltaic cell 16 may be further defined as a thin film and may be disposed directly onto the superstrate 20 by chemical vapor deposition or another suitable method. Relative to FIGS. 1-6, 8, and 9, completed modules 10 are shown. However, it is to be understood that the modules 10 are shown in completed form simply for the sake of simplicity. Each of the substrate 14, photovoltaic cell 16, tie layer 18 or precursor thereof (which is described in detail below), and superstrate 20 are typically placed in the cell press 12 individually and compressed together to form the completed module 10. Each of the substrate 14, photovoltaic cell 16, tie layer 18 or precursor thereof, and superstrate 20 could be shown separately in any one or more of the Figures and then compressed to form the module 10.

Typically, the substrate 14 (e.g. a backsheet) provides protection to a rear surface 22 of the module 10 while a superstrate 20 typically provides protection to a front surface 24 of the module 10. The substrate 14 and the superstrate 20 may be the same or may be different and each may independently include any suitable material known in the art. The substrate 14 and/or superstrate 20 may be soft and flexible or may be rigid and stiff. Alternatively, the substrate 14 and/or superstrate 20 may include rigid and stiff segments while simultaneously including soft and flexible segments. The substrate 14 and superstrate 20 may be transparent to light, may be opaque, or may not transmit light (i.e., may be impervious to light). However, at least one of the substrate 14 and superstrate 20 must allow some light to enter the module 10 and contact the photovoltaic cell 16. Typically, the superstrate 20 transmits light while the substrate 14 does not. The substrate 14 is typically the bottom layer of the module 10 while the superstrate 20 is typically the top and outermost layer that is transparent to the solar spectrum (e.g. visible light) and positioned in front of a light source. The superstrate 20 may be used to protect the module 10 from environmental conditions such as rain, snow, and heat. Most typically, the superstrate 20 is a rigid glass panel that is transparent to sunlight and is used to protect the front surface 24 of the module 10.

In one embodiment, the substrate 14 and/or superstrate 20 are glass. Alternatively, the substrate 14 or superstrate 20 includes metal foils, polyimides, ethylene-vinyl acetate copolymers, and/or organic fluoropolymers such as ethylene tetrafluoroethylene (ETFE), Tedlar®, polyester/Tedlar®, Tedlar®/polyester/Tedlar®, polyethylene terephthalate (PET) alone or coated with silicon and oxygenated materials (SiOₓ), and combinations thereof. In one embodiment, the substrate 14 is further defined as a PET/SiOₓ-PET/Al substrate 14, wherein x has a value of from 1 to 4.

The substrate 14 and/or superstrate 20 may be load bearing or non-load bearing and may be included in any portion of the module 10. Typically, the substrate 14 is load bearing. The substrate 14 may be a “bottom layer” or an outermost layer of the module 10 that is typically positioned behind the photovoltaic cell 16 and serves as mechanical support. In various embodiments, the substrate 14 and/or superstrate 20 are as described in WO 2010/051355, as first introduced above. The substrate 14 and/or superstrate 20 may include a plurality of fibers coated with, for example, a silicone composition. Suitable, but non-limiting, silicone compositions are also described in WO 2010/051355, as first introduced above. Alternatively, the module 10 may include a second or additional substrate 14 and/or superstrate 20.

The photovoltaic cell 16 typically has a thickness of from 1 to 500, from 1 to 5, from 1 to 20, from 300 to 500, from 50 to 250, from 100 to 225, or from 175 to 225, micrometers. The photovoltaic cell 16 also typically has a length and width (not shown in the Figures) of from 100×100 cm to 200×200 cm. In one embodiment, the photovoltaic cell 16 has a length and width of 125 cm each. Alternatively, the photovoltaic cell 16 has a length and width of 156 cm each.

The photovoltaic cell 16 may include large-area, single-crystal, single layer p-n junction diodes. These photovoltaic cells 16 are typically made using a diffusion process with silicon wafers. Alternatively, the photovoltaic cell 16 may include thin epitaxial deposits of (silicon) semiconductors on lattice-matched wafers. In this embodiment, the epitaxial photovoltaics may be classified as either space or terrestrial and typically have AMO efficiencies of from 7 to 40%. Further, the photovoltaic cell 16 may include quantum well devices such as quantum dots, quantum ropes, and the like, and also include carbon nanotubes. These types of photovoltaic cells 16 can have up to a 45% AMO production efficiency.

The photovoltaic cell 16 may include amorphous silicon, monocrystalline silicon, polycrystalline silicon, microcrystalline silicon, nanocrystalline silica, cadmium telluride, copper indium/gallium selenide/sulfide, gallium arsenide, polyphenylene vinylene, copper phthalocyanine, carbon fullerenes, and combinations thereof in ingots, ribbons, thin films, and/or wafers. The photovoltaic cell 16 may also include light absorbing dyes such as ruthenium organometallic dyes. Most typically, the photovoltaic cell 16 includes monocrystalline and polycrystalline silicon. In various embodiments, the photovoltaic cell 16 is as described in WO 2010/051355, as first introduced above.

In one embodiment, the photovoltaic cell 16 is disposed on the substrate 14 via chemical vapor deposition or sputtering and the tie layer 18 or precursor thereof is disposed on and in direct contact with the photovoltaic cell 16. After the photovoltaic cell 16 is disposed on the substrate 14 using sputtering or chemical vapor deposition processing techniques, one or more electrical leads (not shown in the Figures) may be attached to the photovoltaic cell 16. One or more additional layers may then be applied over the electrical leads.

The tie layer 18 is typically formed from a precursor (e.g. a curable composition) that, upon curing, forms the tie layer. The tie layer 18 is typically formed after the precursor is cured, either partially or entirely. The tie layer 18, after cure, and the precursor may have the same viscosity or different viscosities. The cure mechanism may include any known in the art. The precursor need not cure or even partially cure to form the tie layer 18.

The precursor has a shear viscosity of less than about 1,500 cPs measured at 25° C., typically before curing (if the precursor eventually cures). In various embodiments, the precursor may have a shear viscosity of less than or about 1,400, 1,300, 1,200, 1,100, 1,000, 900, 800, 700, 600, 500, 400, 300, 200, or 100, cPs measured at 25° C. before, during, or after curing (if the precursor eventually cures). In other embodiments, the precursor may have a shear viscosity of from 100 to 1,100, 200 to 900, 300 to 800, 400 to 700, or 500 to 600, cPs measured at 25° C. before, during, or after curing (if the precursor eventually cures). In still other embodiments, the precursor may have a shear viscosity of about 1,100, about 600, or about 400, cPs measured at 25° C. before, during, or after curing (if the precursor eventually cures). Typically, the aforementioned viscosities are measured using a Brookfield DVIII Cone and Plate Viscometer at 25° C. according to ASTM D4287, e.g. using a CPE 51 spindle. If the precursor cures to form the tie layer, the tie layer may have a shear viscosity that is higher than about 1,500 cPs measured at 25° C. using the equipment described above. It is also contemplated that the viscosity may be measured using an absolute rotary method, as known in the art.

In one embodiment, the precursor is uncured before compression, i.e., before each of the substrate 14, photovoltaic cell 16, precursor, and superstrate 20 are placed in the cell press and compressed together. Alternatively, the precursor is partially cured before compression. In still another embodiment, the precursor is cured and is further defined as the tie layer before compression.

A second tie layer, as first introduced above, may be utilized that may be the same or different from the tie layer 18 and may be further defined as any one of the options for the tie layer 18 described herein. The second tie layer may also be formed from a second precursor (e.g. a second curable composition) that may be the same or different from the precursor described above. The tie layer 18 and/or the second tie layer, and any corresponding precursors, may be as described in WO 2010/051355, as first introduced above and expressly incorporated herein by reference. Typically, the second tie layer, if utilized, also has a shear viscosity less than about 1,000 cps measured at 25° C. However, the second tie layer is not limited to such a viscosity.

In one embodiment, the precursor includes silicon atoms. The precursor may be free of silicon atoms (or silicone compounds). When including silicon atoms, the precursor may be cured by any means known in the art such as direct processes, hydrolysis, condensation, silylation, hydrosilylation, redistribution, nucleophilic displacement, and the like. In one embodiment, the precursor is cured by hydrosilylation and includes a diorganopolysiloxane having alkenyl groups, a cross-linking agent having silicon-bonded hydrogen atoms, and a hydrosilylation catalyst. The diorganopolysiloxane, cross-linking agent, and hydrosilylation catalyst may be any known in the art or those described in WO 2010/051355, as first introduced above. In various embodiments, a mole ratio of silicon-bonded hydrogen atoms in the cross-linking agent to alkenyl groups in the diorganopolysiloxane is greater than 1, 1.1, 1.2, 1.3, 1.4, or 1.5. In other embodiments, the mole ratio is about 1 or less than 1, 0.9, 0.8, 0.7, 0.6, or 0.5. The precursor may have a shear viscosity of less than 500 cPs measured at 25° C., wherein the diorganopolysiloxane is further defined as a polydimethylsiloxane having two terminal alkenyl groups per molecule, and wherein the cross-linking agent is selected from the group of dimethylhydrogen terminated dimethyl siloxanes, dimethyl-methylhydrogen siloxanes that are trimethylsiloxy terminated, and combinations thereof.

The precursor, and the tie layer prepared therefrom, may include carbon atoms and/or organic compounds and be substantially free of (i.e., include less than 1, 0.5, 0.1, or 0.01 weight percent of) including silicon atoms. In various other embodiments, the precursor, and the tie layer prepared therefrom, includes at least one of an ethylene-vinyl acetate copolymer, a polyurethane, an ethylene tetrafluoroethylene, a polyvinylfluoride, a polyethylene terephthalate, and combinations thereof. The foregoing precursors, and the tie layers prepared therefrom, may be substantially free of compounds including silicon atoms. Conversely, the precursor, and the tie layer prepared therefrom, may be substantially free of (i.e., include less than 1, 0.5, 0.1, or 0.01 weight percent of) carbon atoms, other than any carbon atoms in silicon-bonded organic groups, and/or inorganic compounds.

The module 10 is formed with the use of the cell press 12, first introduced above. The cell press 12 has a longitudinal axis (A), two surfaces 26, 28 disposed opposite each other along the longitudinal axis (A), and a fluidic mechanism 30 for moving at least one of the two surfaces 26, 28 towards the other two surfaces 26, 28.

The longitudinal axis (A) extends vertically through the cell press 12 establishing a reference point for the cell press 12 relative to the ground. The two surfaces 26, 28 are typically oriented vertically along the longitudinal axis (A) relative to gravity and the ground such that one of the two surfaces 26, 28 is further defined as a top surface and the other of the two surfaces is further defined as a bottom surface of the cell press 12. In one embodiment, the fluidic mechanism 30 moves the top surface towards the bottom surface. Alternatively, the fluidic mechanism 30 moves the bottom surface towards the top surface. In still another embodiment, the fluidic mechanism 30 moves the top and bottom surfaces toward each other. Two or more fluidic mechanisms may be utilized.

The disclosure is not limited to such the configurations described above. For example, the cell press 12 may be turned on its side such that longitudinal axis (A) extends approximately parallel with the ground and the top and bottom surfaces are further defined as left/right or opposing surfaces. In this embodiment, the movement along the longitudinal axis (A) is from left to right, right to left, or from both right and left.

In one embodiment, the two surfaces 26, 28 are further defined as the surfaces of a plate 34 and a table 32. Alternatively, one of the two surfaces 26, 28 may be further defined as the surface of the plate 34 or the surface the table 32. Typically, the two surfaces 26, 28 are outermost surfaces, e.g. outermost surfaces of the plate 34 and the table 32. Typically, the plate 34 is oriented above the table 32, relative to the ground.

The cell press 12 is typically maintained stationary and positioned horizontally to support components of the module 10 (e.g. substrate 14, superstrate 20, tie layer 18 or precursor thereof, and photovoltaic cell 16) prior to, during, and subsequent to formation of the module 10, as is described in greater detail below. A shuttle plate 38 can be used to transport the substrate 14, superstrate 20, photovoltaic cell 16, and/or tie layer 18 or precursor thereof, between the two surfaces 26, 28 and/or into the cell press 12 itself.

At least one of the two surfaces 26, 28, e.g. the surfaces of the plate 34 and/or the table 32, and thus at least one of the plate 34 and table 32 themselves, is typically moveable relative to the other. For example, the plate 34 can be stationary with the table 32 moveable relative to the plate 34. Alternatively, the table 32 can be stationary with the plate 34 moveable relative to the table 32. Both the table 32 and plate 34 can be moveable towards each other. In the configuration shown in the Figures, the table 32 and plate 34 are maintained approximately parallel to each other to evenly distribute pressure between the two surfaces 26, 28 during formation of the module 10.

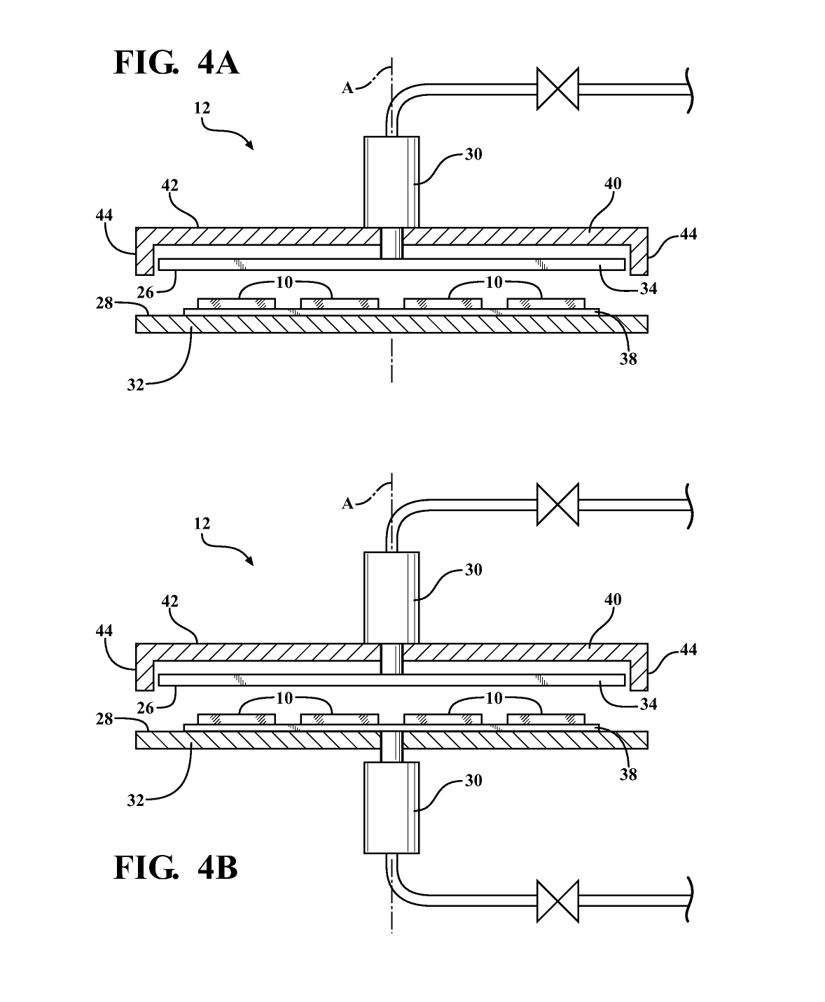

The cell press 12 can include a lid 40 with the plate 34 coupled to the lid 40 and disposed between the lid 40 and the table 32, as shown in FIGS. 4-6, 8, and 9. The plate 34 may be moveable relative to the lid 40 both toward and away from the table 32. The plate 34 may be moved relative to the lid 40 by the fluidic mechanism 30, as described in greater detail below, or may be moved using an independent mechanism. The lid 40 and the table 32 may also be moveable relative to one another. Typically, the table 32 remains stationary and the lid 40 and/or plate 34 move toward and away from the table 32. It should be appreciated that the lid 40 and the table 32 can move relative to each other translationally or rotationally, i.e., about a hinge. It should also be appreciated that the lid 40 and the table 32 can be moved relative to each other by manual operation or through use of the fluidic mechanism 30. The lid 40 may be configured to hermetically seal to the table 32. Typically, the lid 40 includes a top wall 42 and side walls 44. Ends of side walls 44 may be designed to hermetically seal with the table 32 when brought into contact with the table 32 through a lid seal.

The plate 34 and/or the table 32 may each be further defined as platen 46, i.e., approximately flat plates used to compress and form the module 10. The platen 46 are not limited in design. In various embodiments, the terminology plate 34, table 32, and platen 46 may be used interchangeably. However, each may be different from the next. Alternatively, as shown in the Figures the two surfaces 26, 28 may be further defined as the surfaces of one or both platen 46. As such, one or both of the platen 46 can exert an upward and/or downward force (relative to the longitudinal axis (A)) on the module 10 that is being formed thus compressing the substrate 14, photovoltaic cell 16, tie layer 18 or precursor thereof, superstrate 20, and any additional layers or components. The platen are not limited in dimensions or composition. Typically, the platen are metal, plastic, or combinations thereof.

The plate 34 and/or the table 32 may each be further defined as an inflatable bladder 36 or the inflatable bladder 36 may be disposed on the plate 34 and/or the table 32. Alternatively, the two surfaces 26, 28 may be further defined as the surfaces of one or more inflatable bladders 36. In one embodiment, the cell press 12 includes the inflatable bladder 36 and one of the two surfaces 26, 28 is further defined as an outermost surface of the inflatable bladder 36. The inflatable bladder 36 may be disposed on the plate 34 or the table 32 such that the outermost surface of the inflatable bladder 36 faces towards the module 10, when the cell press 12 is in use. The inflatable bladder 36 may be coupled to the plate 34 or the table 32 by any means known in the art.

Typically, the inflatable bladder 36 is semi-rigid and may be formed from silicone, polymers, plastics, and the like. The inflatable bladder 36 is not limited to any particular dimensions and is typically filled with air and/or a liquid. The air and/or the liquid may be heated to a temperature that is greater than room temperature and may be pressurized to a pressure that exceeds atmospheric pressure. i.e., greater than about 14 or 15 psi. In various embodiments, the air and/or the liquid are heated to temperatures of from 20 to 200, from 20 to 100, from 25 to 95, from 30 to 90, from 35 to 85, from 40 to 80, from 45 to 75, from 50 to 70, from 55 to 65, or from 55 to 60, ° C. In one embodiment, the air and/or liquid is heated to a temperature of from 130° C. to 140° C. The inflatable bladder 36 may be completely filled or less than completely filled during use, for example, filled to 100%, 90%, 80%, or 70%. Typically, when filled, the inflatable bladder 36 exerts an upward or downward force (relative to the longitudinal axis (A)) on the module 10 that is being formed thus compressing the substrate 14, photovoltaic cell 16, tie layer 18 or precursor thereof, superstrate 20, and any additional layers or components.

The inflatable bladder 36 is not limited in design and may include a single chamber or two or more chambers (not shown in the Figures). The chambers may be integral or fluidly connected. Said differently, the chambers may be a single units or may be further defined as independent units. In one embodiment, the inflatable bladder includes an inner chamber and an outer chamber. As such, in one embodiment of the method, the method further includes the steps of inflating the inner chamber and subsequently inflating the outer chamber to exert pressure on the substrate 14, photovoltaic cell 16, tie layer 18 or precursor thereof, and superstrate 20 in a direction from the inner chamber towards the outer chamber. Said differently, in this embodiment, the center of the inflatable bladder is inflated first and the inflation proceeds from the center towards the edges thereby promoting displacement of air bubbles from the center of the tie layer 18/precursor/module 10 towards the edges and eventually out of the tie layer 18/precursor/module 10.

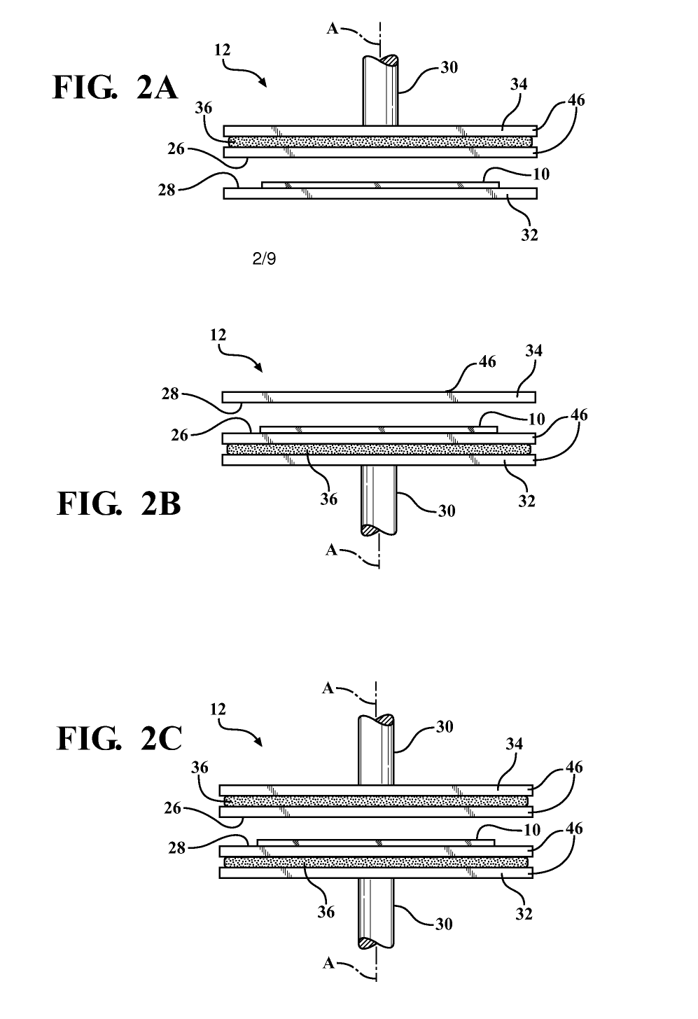

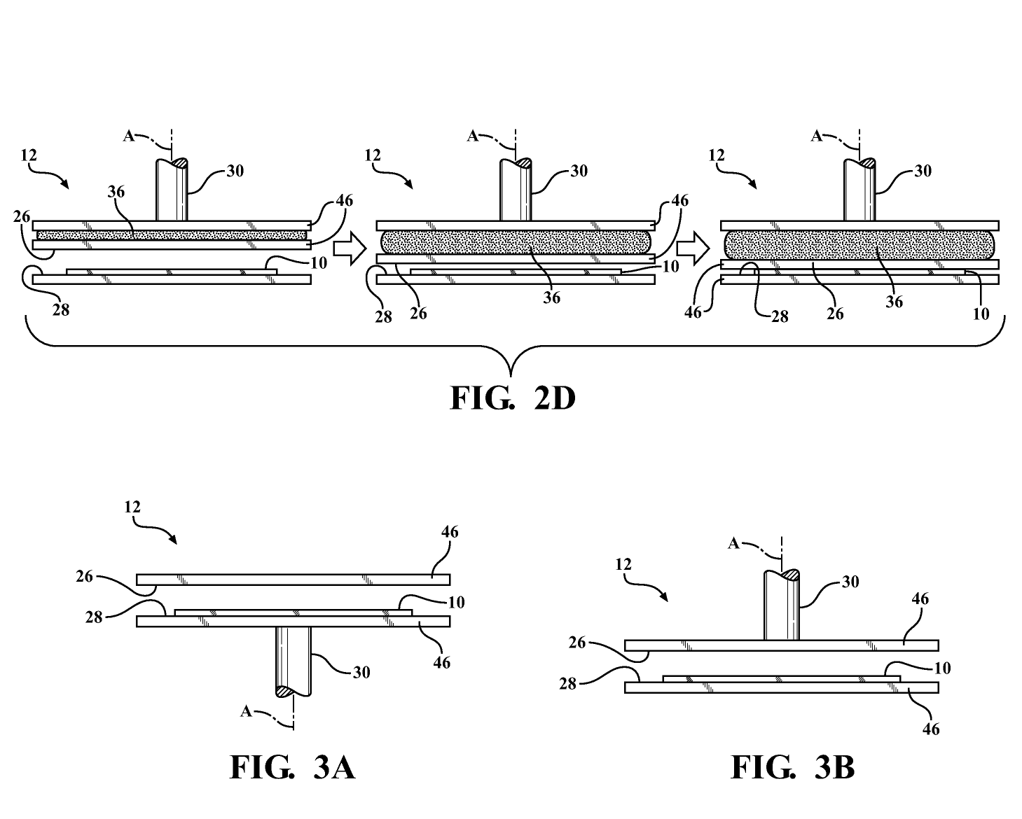

In one embodiment, as shown in FIG. 2, the cell press 12 includes three platen 46 as described above and the inflatable bladder 36. In this embodiment, two platen 46 sandwich the inflatable bladder 36 while a third platen 46 is disposed apart from the inflatable bladder 36. Accordingly, when the inflatable bladder 36 expands, the inflatable bladder 36 exerts an upward or downward force (relative to the longitudinal axis (A)) on the module 10 that is being formed thus compressing the substrate 14, photovoltaic cell 16, tie layer 18 or precursor thereof, superstrate 20, and any additional layers or components between two of the platen 46.

Alternatively, the cell press 12 may include two platen 46 as described above, two addition platen 46, and two inflatable bladders 36, as shown in FIG. 2C. In this embodiment, each of the two inflatable bladders 36 is sandwiched between two platen 46 such that one inflatable bladder 36 exerts a downward force and the other inflatable bladder 36 exerts an upward force, when inflated.

Any of the surfaces 26, 28, table 32, plate 34, inflatable bladders 36, or platen 46 described above may be heated or cooled and may include a release agent disposed thereon to reduce adhesion between the surface and the substrate 14 or superstrate 20. The release agent is not limited and may be a Kevlar sheet. Typically, one or more of the surfaces 26, 28, table 32, plate 34, inflatable bladders 36, or platen 46 are heated using electrical coils, flame, heated air (gas), or heated liquid. The disclosure is not limited to these methods of heating.

Referring back to the fluidic mechanism 30, this mechanism does not include mechanical gears that move the surfaces 26, 28 along the longitudinal axis (A). However, gears may be used in other capacities in the fluidic mechanism 30. For example, one or both of the surfaces 26, 28, may be moved using mechanical mechanisms such as gears or screws and then the fluidic mechanism 30 can further move one or both surfaces 26, 28. Alternatively, the cell press 12 may be free of mechanical gears or non-fluidic mechanisms either entirely or relative to moving the surfaces 26, 28. Said differently, the cell press may include only fluidic mechanisms 30 to move the surfaces 26, 28 but optionally may include mechanical mechanisms, e.g. gears or screws, to perform other functions. The fluidic mechanism 30 is further defined as a mechanism that operates using fluids, e.g. air (gas) or liquids but is not limited in design. In one embodiment, the fluidic mechanism 30 is further defined as a hydraulic mechanism which utilizes hydraulic fluids. Alternatively, the fluidic mechanism 30 is further defined as a pneumatic mechanism which utilizes gas or air. Typical air and/or liquid pressures that are utilized are from 5 to 100, from 25 to 90, from 35 to 80, from 45 to 70, from 55 to 60, or from 45 to 55, psi. These pressures may translate into pressures exerted on the substrate 14, the tie layer 18 or precursor thereof, the photovoltaic cell 16, and/or the superstrate 20 that are the same as those above, or from 1 to 50, 5 to 45, 10 to 40, 15 to 35, 20 to 30, or 25 to 30, psig. The fluidic mechanism 30 may operate at a single pressure or at pressures that vary. Similarly, the pressure exerted on the substrate 14, the tie layer 18 or precursor thereof, the photovoltaic cell 16, and/or the superstrate 20 may be constant or may vary. In one embodiment, an initial pressure of from 1 to 10, from 1 to 5, or from 5 to 10, psig, is exerted on the substrate 14, the tie layer 18 or precursor thereof, the photovoltaic cell 16, and/or the superstrate 20 and then ramped upwards to a final pressure of from 25 to 30, psig. The pressure may be held or may vary for times of from seconds to minutes. These times are not limited.

As first described above, the cell press 12 may include two or more fluidic mechanisms 30. For example, in embodiments that include two or more inflatable bladders 36 or those in which both the surfaces 26, 28 are moveable relative to each other, two or more fluidic mechanisms 30 may be utilized. The fluidic mechanism 30 may include one or more air hoses that inflate to move one of the two surfaces 26, 28 along the longitudinal axis (A) towards the other of the two surfaces 26, 28. Two or more fluidic mechanisms 30 may be utilized to operate two or more inflatable bladders 36, two or more sets of platen 46, and/or combinations thereof.

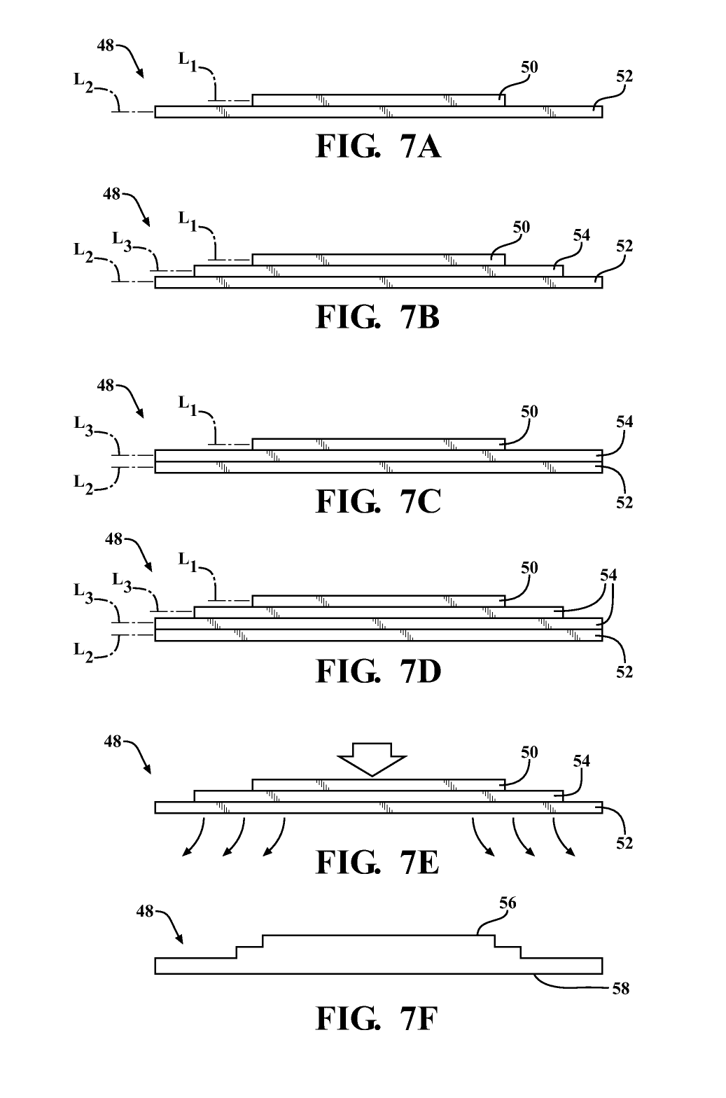

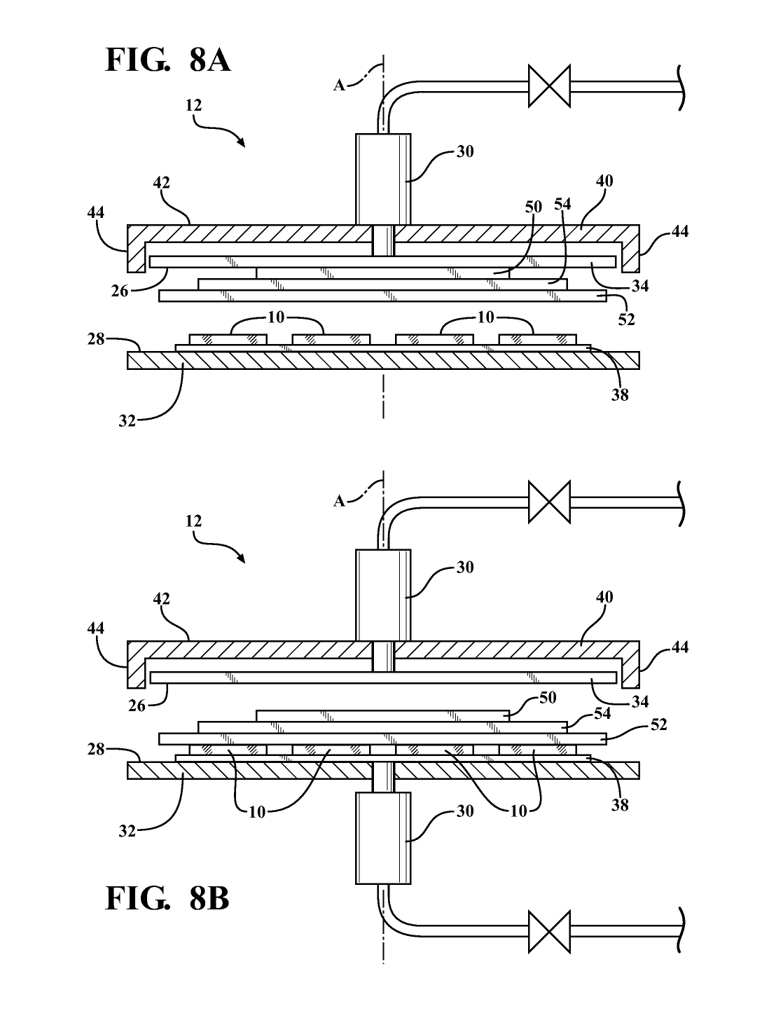

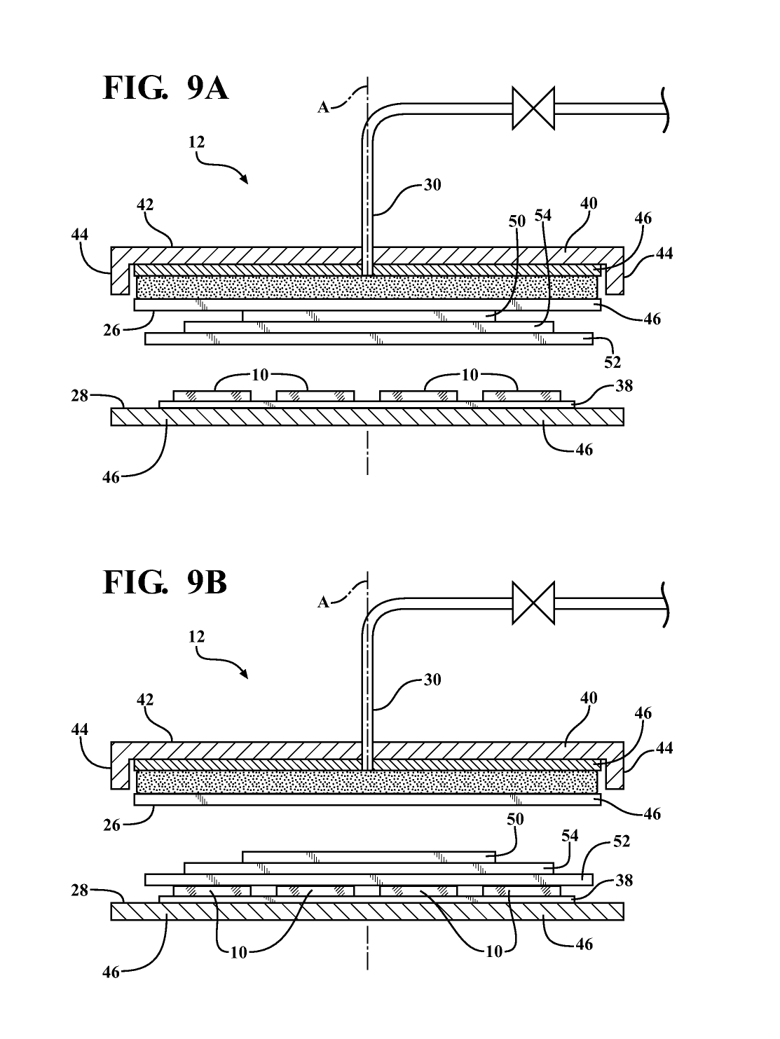

The cell press 12 and or method may also include or utilize an insert 48 for contacting the substrate 14 or superstrate 20. The insert 48 is not limited in design. Typically, at least one of the two surfaces 26, 28 compresses the substrate, photovoltaic cell, tie layer or precursor thereof, and superstrate through the insert 48 to form the module 10. The insert may be integral (as in FIG. 7F) or may include discrete layers (as in FIGS. 7A-7E). The insert 48 may be disposed in contact with (e.g. connected to) one or more of the surfaces 26, 28, table 32, plate 34, inflatable bladders 36, or platen 46. Alternatively, the insert 48 may be disposed in contact with one or more substrates 14 and/or superstrates 20 and not connected to one or more of the inflatable bladder 36, platen 46, plate 34, and/or table 32. For example, the insert 48 may be disposed on top of the substrate 14 and/or superstrate 20, as shown in FIGS. 8B and 9B.

The cell press 12 may include or utilize one or more than one insert 48. In one embodiment, the cell press 12 utilizes two inserts and one insert 48 is disposed in contact with the one of the surfaces 26, 28 and the second insert 48 is disposed in contact with the other of the surfaces 26, 28 (not shown in the Figures). Alternatively, two or a plurality of inserts 48 may be utilized simultaneously. The insert 48 may be shaped pyramidally or approximately pyramidally. Alternatively, the insert 48 may be shaped to have a top that is smaller than a bottom, wherein the bottom is designed to contact the substrate 14 or superstrate 20. In one embodiment, the insert 48 includes multiple layers such that each successive layer measured from the top to the bottom increases in size. Alternatively, the insert 48 may be shaped such that the sizes of individual layers, or of various portions of the insert 48 itself, cascade in size from smaller to larger from the top to the bottom. The insert 48 is typically shaped in one or more of the aforementioned ways such that the force from the cell press is focused on a small surface initially and then spread downwards and outwards to progressively larger surfaces from a center of the insert 48 to the edges of the insert 48 and thus from a center of the module 10 to edges of the module 10. Typically, the force is distributed laterally away from the longitudinal axis (A) of the cell press 12 towards the edges of the insert 48 and the edges of the module 10. This promotes displacement of air bubbles from the center of the module 10 towards the edges of the module 10 and out of the module 10.

The insert 48 has a first outermost surface 56 and a second outermost surface 58. When the insert 48 includes discrete layers, the insert 48 may also include first and second outermost layers 50, 52. In this embodiment, the first and second outermost surfaces 56, 58 are the surfaces of the first and second outermost layers 50, 52.

The first outermost surface/layer 56/50 is typically disposed proximal to one of the two surfaces 26, 28 of the cell press 12 moveable by the fluidic mechanism 30. In this embodiment, the second outermost surface/layer (58/52) is disposed distal to that same surface. The first and second outermost surfaces 56, 58 and/or layers 50, 52 are typically disposed substantially parallel to each other. As shown in FIG. 7A, the first outermost surface 56 is disposed on a “top” of the insert 48 while the second outermost surface 58 is disposed on a “bottom” of the insert 48.

The first outermost surface 56 typically defines a two-dimensional surface area proximal to the surface 26, 28 of the cell press 12 moveable by the fluidic mechanism 30 while the second outermost surface 58 defines a two-dimensional surface area distal to the surface 26, 28 of the cell press 12 moveable by the fluidic mechanism 30, as shown in FIG. 7. The two-dimensional surface area of the second outermost surface 58 is typically disposed to contact the substrate 14 or superstrate 20. In other words, the second outermost surface 58 itself is typically disposed to contact the substrate 14 or superstrate 20. The two-dimensional surface area of the first outermost surface 56 is typically less (smaller) than the two-dimensional surface area of the second outermost surface 58 for distributing force to the substrate 14, photovoltaic cell 16, tie layer 18 or precursor thereof, and superstrate 20, during compression, in a direction lateral to the longitudinal axis (A) of the cell press 12.

This two-dimensional surface area of the first outermost surface 56 can be further defined when the first outermost surface 56 is disposed on the insert 48 furthest from the substrate 14 and/or superstrate 20 and thus closest to one of the surfaces 26, 28 of the cell press. Similarly, the two dimensional surface area of the second outermost surface 58 can be further defined when the second outermost surface 58 is disposed on the insert 48 closest to the substrate 14 and/or superstrate 20.

The terminology “two-dimensional surface area” typically refers to an X/Y coordinate surface area of the first and/or second outermost surfaces 56, 58. Typically, this two-dimensional surface area describes one face/plane of the first and second outermost layers 50, 52 and does not include any surface area associated with any other sides, edges, corners, or the like, of the layers 50, 52.

The insert 48 may also include one or more intermediate layer(s) 54 disposed between the first and second outermost layers 50, 52. In one embodiment, the insert 48 includes two or more (e.g. a plurality) of intermediate layers 54. Each intermediate layer 54 is typically disposed parallel to the first and second outermost surfaces 56, 58 and/or the first and second outermost layers 50, 52 and typically parallel to the substrate 14, tie layer 18 or precursor thereof, photovoltaic cell 16, superstrate 20, platen 46, inflatable bladder 36, table 32, and/or plate 34, when in the cell press 12. Each intermediate layer 54 may have an intermediate latitudinal axis (L₃) that may be disposed substantially parallel to the first and second latitudinal axes (L₁ and L₂). Most typically, each intermediate latitudinal axis (L₃) is also substantially parallel to the substrate 14, tie layer 18 or precursor thereof, photovoltaic cell 16, superstrate 20, platen 46, inflatable bladder 36, table 32, and/or plate 34, when in the cell press 12.

Each intermediate layer 54 has a surface defining a two-dimensional surface area distal to the surface 26, 28 of the cell press 12 moveable by the fluidic mechanism 30 (i.e., opposite from the first outermost surface 56). The two-dimensional surface areas of the intermediate layers 54 are typically greater than the two-dimensional surface area of the first outermost surface 56. The two-dimensional surface area of the surface of at least one intermediate layer 54 described immediately above may be less than the two-dimensional surface area of the second outermost surface 58 or may be approximately the same.

As shown in FIG. 7B, the two-dimensional surface area of the surface of the intermediate layer 54 may be further defined as the two-dimensional surface area of the face/plane of the intermediate layer 54 that is in direct contact with the second outermost layer 52. Typically, the two-dimensional surface area of the surface of each intermediate layer 54 is greater than the two-dimensional surface area of the first outermost surface 56. As also shown in FIG. 7B, the two-dimensional surface area of the surface of at least one intermediate layer 54 is typically less than the two-dimensional surface area of the second outermost surface 58. Alternatively, as shown in FIG. 7C, the two-dimensional surface area of the surface of at least one intermediate layer 54 is approximately equal to the two-dimensional surface area of the second outermost surface 58.

Further, the insert may include two or more intermediate layers 54 and the two-dimensional surface areas of the surfaces of each of the two or more intermediate layers 54 tends to increase in size when sequentially measured in the direction from the first outermost layer 50 towards the second outermost layer 52. In other words, when viewing the insert 48 from the first outermost layer 50 towards the second outermost layer 52, the two-dimensional surface areas of each surface of the intermediate layers 54 therebetween tends to increase in size as compared to one or more immediately preceding intermediate layers 54. An intermediate layer 54 disposed immediately adjacent to the first outermost layer 50 typically has a surface with a smaller two-dimensional surface area than the surface of an intermediate layer 54 disposed immediately adjacent to the second outermost layer 52. Most typically, the insert 48 is approximately pyramidal shaped, as shown in FIG. 7B.

The first and second outermost layers 50, 52 and the at least one intermediate layer(s) 54 are not limited in dimensions except that the two-dimensional surface area of the first outermost surface 56 is typically less than the two-dimensional surface area of the second outermost surface 58, as described above. The insert 48 may be sized to be used with a single module 10, more than one module 10, or an array of modules 10, simultaneously, in the cell press 12. Most typically, the insert 48 is sized such to contact more than one module 10 in the cell press 12 simultaneously.

The insert 48 is also not limited to any particular dimensions or numbers of layers. The insert 48 may be free of intermediate layers. In various embodiments, the insert 48 includes a total of 3, 4, 5, 6, 7, 8, 9, or 10+ total layers. Typically, the insert 48 includes 3 to 5 or 3 to 7, layers. In one embodiment, the insert 48 includes 5 layers. In various embodiments, one or more of the layers has a thickness of from about 1/16 inch to ⅜ inch. In one embodiment, one or more of the layers has a thickness of about ⅛ inch.

The insert 48 as a whole, along with the first and second outermost layers 50, 52 and the at least one intermediate layer(s) 54, are also not limited relative to composition. The insert 48, and/or one or more of the first and second outermost layers 50, 52 and/or at least one intermediate layer 54, may include paper, cardboard, foam, plastic, metal, wood, or polymers. The composition of one or more of the first and second outermost layers 50, 52 and/or the at least one intermediate layer(s) 54 may all be the same or may be different. Similarly, the composition of the insert 48 as a whole may be homogeneous or may be heterogeneous and be different in various portions of the insert 48. In one embodiment, the compositions of the layers 50, 52, and/or 54 alternate. The layers 50, 52, and/or 54 may vary in composition, e.g. foam (first outermost layer 50), foam (intermediate layer 54), foam (intermediate layer 54), cardboard (intermediate layer 54), and foam (second outermost layer 52). The first and second outermost layers 50, 52 and the at least one intermediate layer(s) 54 are typically adhered together. However, this is not required.

Referring back to the method of forming the module 10, the method provides for the assembly of the substrate 14, the tie layer 18 or precursor thereof, the photovoltaic cell 16, and the superstrate 20. More specifically, the method includes the step of disposing the substrate 14, photovoltaic cell 16, tie layer 18 or precursor thereof, and superstrate 20 between the two surfaces 26, 28 and spaced from one of the surfaces 26, 28. The method may include the step of disposing the photovoltaic cell 16 on the substrate 14 via chemical vapor deposition (CVD).

Each one of the substrate 14, photovoltaic cell 16, tie layer 18 or precursor thereof, and superstrate 20 (and any additional components or layers) may be disposed individually or in combination with one or more of the others between the two surfaces 26, 28. Typically, each of the substrate 14, photovoltaic cell 16, tie layer 18 or precursor thereof, and superstrate 20 are disposed between the surfaces 26, 28 individually. It should be appreciated that the method can be used to form one module 10, more than one module 10, or an array of modules 10, either separately or in combination and either sequentially or simultaneously. The tie layer 18 or precursor thereof may be disposed between the two surfaces 26, 28 as the precursor uncured, partially cured, or completely cured. Said differently, the step of disposing the tie layer between the two surfaces 26, 28 may be alternatively described as disposing the precursor uncured, partially cured, or completely cured, between the two surfaces 26, 28. The method may also include the step of curing the precursor to form the tie layer 18 before, during, or after compression, i.e., compressing the substrate 14, photovoltaic cell 16, tie layer 18 or precursor thereof, and superstrate 20.

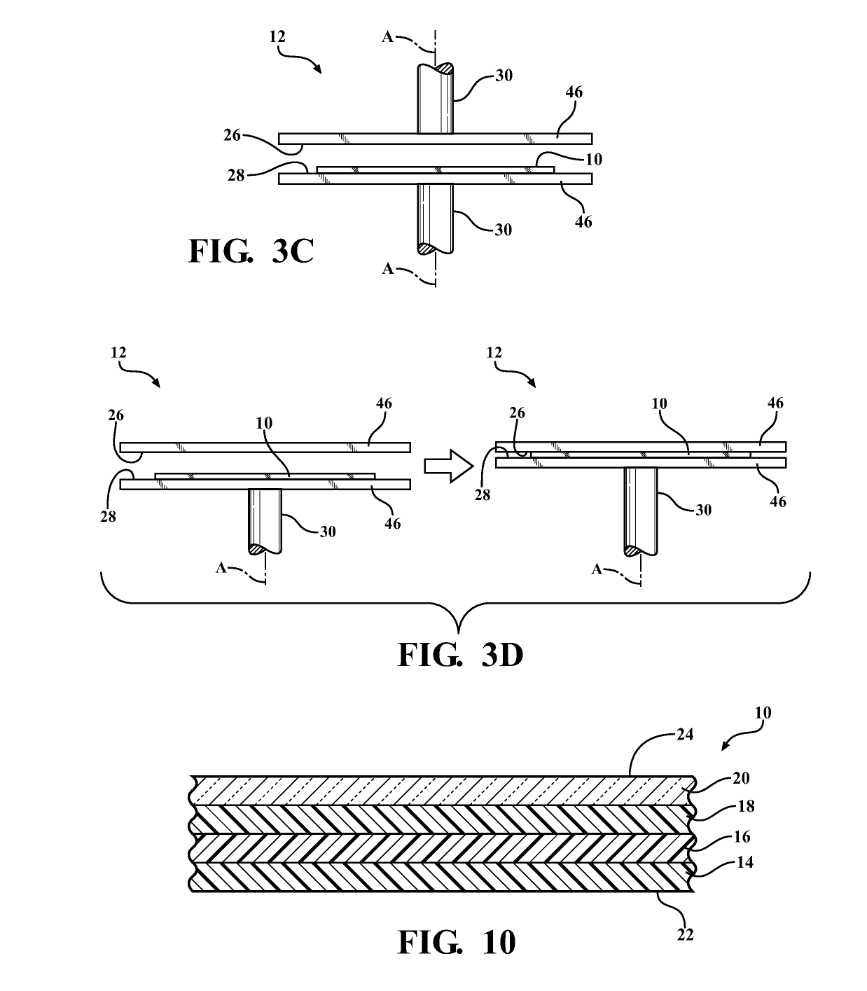

The method also includes the step of moving at least one of the two surfaces 26, 28 along the longitudinal axis (A) towards the other of the two surfaces 26, 28 using the fluidic mechanism 30 to compress the substrate 14, photovoltaic cell 16, tie layer 18 or precursor thereof, and superstrate 20 and form the photovoltaic cell 16 module 10. This may be further defined as moving one of the surfaces 26, 28 along the longitudinal axis (A) towards the other of the surfaces 26, 28 using the fluidic mechanism 30 until the substrate 14 contacts one of the two surfaces 26, 28 and the superstrate 20 contacts the other of the two surfaces 26, 28. As described above, the two surfaces 26, 28 may be oriented vertically along the longitudinal axis (A), wherein one of the two surfaces 26, 28 is further defined as the top surface, the other of the two surfaces 26, 28 is further defined as the bottom surface, and the fluidic mechanism 30 moves the top surface towards the bottom surface, as shown in FIG. 3B. Alternatively, the fluidic mechanism 30 can move the bottom surface towards the top surface, as shown in FIG. 3A. Even further, the fluidic mechanism(s) 30 can move the top and bottom surfaces toward each other sequentially or simultaneously.

The step of moving at least one of the two surfaces 26, 28 is typically further defined as utilizing a fluid, i.e., a liquid or gas, in the fluidic mechanism 30. Most typically, the fluid is pressurized in the fluidic mechanism 30, or injected into the fluidic mechanism 30 under pressure. The method does not include (i.e., is free of) the use of a vacuum to operate the fluidic mechanism. More specifically, the method does not utilize a vacuum to create a void or space with little to no air and then utilize or rely on ambient air pressure to fill the void or space to operate the fluidic mechanism or to move the two surfaces 26, 28 together. In other words, no vacuum is used to move the two surfaces 26, 28 towards each other or to create an environment wherein ambient air pressure is used to move the two surfaces 26, 28 towards each other. Most typically, no vacuum is used at all in this method. However, a vacuum may be used in ancillary or secondary steps so long as the vacuum is not used to move the two surfaces 26, 28 towards each other in conjunction with the fluidic mechanism. Typically, pressurized fluid is utilized. Most typically, if the fluid is a gas, the gas is pressurized above atmospheric pressure (e.g. >14-15 psi) to move the two surfaces 26, 28 towards each other. The exclusion of use of a vacuum to move the two surfaces 26, 28 towards each other saves processing times and costs, maintenance times and costs, and increases speed and efficiency.

The method may also include the step of inflating and/or deflating the inflatable bladder 36. As described above, the inflatable bladder 36 may be inflated using air (gas), liquid, and combinations thereof. Typically, the inflatable bladder 36 is inflated using air or liquid at a pressure described above. The inflatable bladder 36 is typically filled in a time of from 0.1 to 30, of from 1 to 25, of from 5 to 20, of from 10 to 15, of from 1 to 10, or of from 1 to 5, seconds. Similarly, the inflatable bladder 36 is typically deflated in a time also within one or more of the aforementioned ranges. The method may also include the step of heating and/or cooling one or more of the surfaces 26, 28, table 32, plate 34, inflatable bladders 36, or platen 46 and/or applying a release agent thereon.

In one embodiment, the method includes positioning the cell press 12 in an open position and moving the plate 34 to a retracted position in the lid 40 and moving the lid 40 away from the table 32. The method may include using the fluidic mechanism 30 to move the plate 34 toward the lid 40 to the retracted position. In this embodiment, with the cell press 12 in the open position, the method includes disposing the substrate 14, the tie layer 18 or precursor thereof, the photovoltaic cell 16, and the superstrate 20 between the two surfaces 26, 28, e.g. between the plate 34 and the table 32. For example, one or more photovoltaic cells 16 may be simultaneously placed on the shuttle plate 38 in an appropriate predetermined position and the shuttle plate 38 may be placed in a predetermined position on the table 32. The substrate 14, the tie layer 18 or precursor thereof, the photovoltaic cell 16, and the superstrate 20 may each be introduced using any suitable means which can be automatically operated, manually operated or robotically operated. For example a multi-axis robot, may be integrated for positioning the substrate 14, the tie layer 18 or precursor thereof, the photovoltaic cell 16, and the superstrate 20 on the shuttle plate 38 or the like or directly onto the table 32. Such a robot may additionally be subsequently used for accurate positioning of one or more additional components onto the table 32 and for removing the module 10 when completed. A robotic gripper, e.g. a device attached to a mounting arm of the robot, for holding and manipulating the substrate 14, the tie layer 18 or precursor thereof, the photovoltaic cell 16, and/or the superstrate 20, may also be used and may include a series of suction cups adapted to hold the substrate 14, the tie layer 18 or precursor thereof, the photovoltaic cell 16, and/or the superstrate 20 in a flat, typically horizontal, plane.

After the substrate 14, the tie layer 18 or precursor thereof, the photovoltaic cell 16, and the superstrate 20 are disposed between the surfaces 26, 28, e.g. between the plate 34 and the table 32, the lid 40 may be moved toward the table 32 and into contact with the table 32. Specifically, a lid 40 seal may contact the table 32 to seal the lid 40 to the table 32. At this point, typically at least one of the two surfaces 26, 28 is moved along the longitudinal axis (A) towards the other of the two surfaces 26, 28 using the fluidic mechanism 30 to compress the substrate 14, the tie layer 18 or precursor thereof, the photovoltaic cell 16, and the superstrate 20 and form the module 10. One or more components or one or more method steps, as described in U.S. application Ser. No. 12/922,390 filed on Sep. 13, 2010, which is expressly incorporated herein by reference, may be used in this disclosure.

A series of modules (Modules 1-3) are formed according to this disclosure and are compared to a series of comparative modules (Comparative Module 1-5) that do not represent this disclosure. The Modules 1-3 are more specifically described as Modules 1A/B, 2A/B and 3A/B.

Module 1A is formed using a platen press of this disclosure and a precursor of a tie layer (tie layer precursor) of this disclosure, wherein the precursor has a shear viscosity of about 400 cps measured at 25° C. before curing. This precursor is a hydrosilylation curable PDMS.

Module 1B is formed using a bladder press of this disclosure and the aforementioned tie layer precursor that has a shear viscosity of about 400 cps measured at 25° C. before curing.

Comparative Module 1 is formed using the same chemistry as Modules 1A/B but not with the cell press of this disclosure. More specifically Comparative Module 1 is formed using a vacuum press.

Module 2A is formed using the aforementioned platen press and a tie layer precursor that has a shear viscosity of about 600 cps measured at 25° C. before curing. This precursor is also a hydrosilylation curable PDMS.

Module 2B is formed using the aforementioned bladder press and the aforementioned tie layer precursor that has a shear viscosity of about 600 cps measured at 25° C. before curing.

Comparative Module 2 is formed using the same chemistry as Modules 2A/B but not with the cell press of this disclosure. More specifically Comparative Module 2 is formed using the aforementioned vacuum press.

Module 3A is formed using the aforementioned platen press and a tie layer precursor that has a shear viscosity of about 1,100 cps measured at 25° C. before curing. This precursor is also a hydrosilylation curable PDMS that includes quartz filler.

Module 3B is formed using the aforementioned bladder press and the aforementioned tie layer precursor that has a shear viscosity of about 1,100 cps measured at 25° C. before curing.

Comparative Module 3 is formed using the same chemistry as Modules 3A/B but not with the cell press of this disclosure. More specifically Comparative Module 3 is formed using the aforementioned vacuum press.

Comparative Module 4 is formed using the aforementioned platen press and a tie layer precursor that does not represent this disclosure and that has a shear viscosity of about 3,000 cps measured at 25° C. before curing. This precursor is also a hydrosilylation curable PDMS that includes quartz filler.

Comparative Module 5 is formed using the aforementioned bladder press and a tie layer precursor that does not represent this disclosure and that has a shear viscosity of about 3,000 cps measured at 25° C. before curing.

To form each of Modules and Comparative Modules, a glass substrate is utilized. Subsequently, a photovoltaic cell is disposed on the glass substrate. Then, one of the aforementioned precursors is disposed on the photovoltaic cell. A glass superstrate is then disposed on, and in direct contact with, the precursor. The combination of the glass substrate, photovoltaic cell, precursor, and glass superstrate is disposed within one of the aforementioned platen press, bladder press, or vacuum press, as described above, to cure the precursor and form the Modules.

To form the Modules and Comparative Modules using the platen press, the combination of the glass substrate, photovoltaic cell, precursor, and glass superstrate is disposed on a lower or bottom platen (i.e., a table) of the platen press which is heated to approximately 100° C. An upper or top platen (i.e., a plate) of the platen press is not heated and includes the insert of this disclosure. The lid of the platen press is then closed and the fluidic mechanism then moves one or both of the two surfaces to compress the glass substrate, photovoltaic cell, precursor, and glass superstrate to form the Modules. More specifically, the pressure is incrementally increased in 5-10 psig increments every 10 seconds from less than about 5 psig up to about 25-30 psig. Once the pressure of 25-30 psig is reached, this pressure is held for about 3.5 minutes. After formation, the modules are removed and visually inspected to evaluate whether the modules are cracked and whether any voids or air bubbles are present.

To form the Modules and Comparative Modules using the bladder press, the combination of the glass substrate, photovoltaic cell, precursor, and glass superstrate is disposed on a lower or bottom platen (i.e., a table) of the bladder press. The lid of the bladder press is then closed. The bladder is contacted with a hot plate at about 135° C. to heat the bladder. The fluidic mechanism then inflates a bladder with air to compress the glass substrate, photovoltaic cell, precursor, and glass superstrate to form the Modules. More specifically, the pressure is incrementally increased from atmospheric pressure up to about 50 psi and held for about 3.5 minutes. After formation, the modules are removed and visually inspected to evaluate whether the modules are cracked and whether any voids or air bubbles are present.

To form the Comparative Modules using the vacuum press, the combination of the glass substrate, photovoltaic cell, precursor, and glass superstrate are disposed on a lower or bottom platen (i.e., a table) of the vacuum press. The lower platen is heated to about 100° C. Subsequently, the lid of the press is lowered and a vacuum is pulled. Due to the vacuum, a bladder that is disposed in the lid fills with atmospheric air (at atmospheric pressure) from the ambient environment and compresses the glass substrate, photovoltaic cell, precursor, and glass superstrate for about 3.5 minutes, i.e., the same approximate time as above using the platen and bladder presses. Since the vacuum is used to create a void in the cell press, ambient air from the environment fills the void by inflating the bladder up to atmospheric pressure (−14-15 psi). However, this is not representative of the method of this disclosure at least because a vacuum is used to move the bladder, because ambient air pressure is used, and because the air is not pressurized or used in a fluidic mechanism of this disclosure. After formation, the modules are removed and visually inspected to evaluate whether the modules are cracked and whether any voids or air bubbles are present. The results of the aforementioned evaluations of structural integrity and presence of air bubbles are summarized in Table 1 set forth immediately below.

TABLE 1

| | Module | Module | Comp. | Module | Module | Comp. |
|---|---|---|---|---|---|---|
| | 1A | 1B | Module 1 | 2A | 2B | Module 2 |
| Shear Viscosity of Precursor (cps) | ~400 | ~400 | ~400 | ~600 | ~600 | ~600 |
| Measured at 25° C. | | | | | | |
| Total Time To Form Module (min) | ~3.5 | ~3.5 | ~3.5 | ~3.5 | ~3.5 | ~3.5 |
| Type of Press Used | Platen | Bladder | Vacuum | Platen | Bladder | Vacuum |
| Cracking | No | No | No | No | No | No |
| Visible Air Bubbles/Voids | No | No | Yes | No | No | Yes |
| Acceptable Module Formed | Yes | Yes | No | Yes | Yes | No |

| | Module | Module | Comp. | Comp. | Comp. |
|---|---|---|---|---|---|
| | 3A | 3B | Module 3 | Module 4 | Module 5 |
| Shear Viscosity of Precursor (cps) | ~1,100 | ~1,100 | ~1,100 | ~3,000 | ~3,000 |
| Measured at 25° C. | | | | | |
| Total Time To Form Module | ~3.5 | ~3.5 | ~3.5 | ~3.5 | ~3.5 |
| Type of Press Used | Platen | Bladder | Vacuum | Platen | Bladder |
| Cracking | No | No | No | No | No |
| Visible Air Bubbles/Voids | No | No | Yes | Yes | Yes |
| Acceptable Module Formed | Yes | Yes | No | No | No |

The use of the fluidic mechanism (platen/bladder press) of this disclosure is compared to the use of a vacuum press in the experiments above. The data associated with these comparisons clearly indicates that the fluidic mechanism allows the cell press of this disclosure to operate very quickly and efficiently because the ingress/egress of fluid from the fluidic mechanism occurs rapidly thereby minimizing cycle time and increasing efficiency. The fluidic mechanism also allows the cell press to exert evenly dispersed and minimized force on the modules thereby reducing breakage and cracking and minimizing the time needed to remove air bubbles and form an acceptable module. Moreover, the fluidic mechanism allows for the force exerted on the module to be accurately customized to further decrease the time needed to remove air bubbles and to further increase efficiency. In addition, the fluidic mechanism is much more convenient and saves time and costs as compared to use of the vacuum press. As is well appreciated in the art, use of vacuum presses is time consuming, labor intensive, and requires significant maintenance, all of which increase the cost and complexity of forming modules.

The data and results also show that a low viscosity of the tie layer precursor allows for more efficient displacement of any air bubbles thereby further increasing the efficiency of the cell press and allowing for formation of acceptable modules. As shown in the data associated with Modules 1-3 and Comparative Modules 4 and 5, if the viscosity of the tie layer precursor is high, e.g. ˜3,000 cps measured at 25° C., the precursor is too viscous to allow air bubbles to effectively escape.

One or more of the values described above may vary by ±5%, ±10%, ±15%, ±20%, ±25%, etc. and/or be any value or range of values (both whole and fractional) within those above so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

1. A method of forming a photovoltaic cell module including a substrate, a photovoltaic cell disposed on the substrate, a tie layer disposed on the photovoltaic cell, and a superstrate disposed on the tie layer, wherein the photovoltaic cell module is formed with the use of a cell press having a longitudinal axis, two surfaces disposed opposite each other along the longitudinal axis, and a fluidic mechanism for moving at least one of the two surfaces towards the other of the two surfaces along the longitudinal axis, said method comprising the steps of:
disposing the substrate, photovoltaic cell, tie layer or a precursor thereof, and superstrate between the two surfaces and spaced from one of the two surfaces; and
moving at least one of the two surfaces along the longitudinal axis towards the other of the two surfaces using the fluidic mechanism to compress the substrate, photovoltaic cell, tie layer or precursor thereof, and superstrate and form the photovoltaic cell module,
wherein the precursor has a viscosity of less than about 1,500 cPs measured at 25° C. before curing.

2. The method of claim 1 wherein the precursor has a viscosity of about 1,100 cPs, of about 600 cps, or of about 400 cps, measured at 25° C. before curing.

3. The method of claim 1 wherein the precursor is uncured before compression or is partially cured before compression.

4. The method of claim 1 wherein the cell press comprises an inflatable bladder and one of the two surfaces is further defined as an outermost surface of the inflatable bladder.

5. The method of claim 4 wherein the inflatable bladder comprises an inner chamber and an outer chamber and said method further comprises the steps of inflating the inner chamber and subsequently inflating the outer chamber to exert pressure on the substrate, photovoltaic cell, tie layer or precursor thereof, and superstrate in a direction from the inner chamber towards the outer chamber.

6. The method of claim 1 wherein the cell press comprises two platen and each of the two surfaces is further defined as an outermost surface of the platen.

7. The method of claim 1 wherein the cell press comprises two platen and an inflatable bladder sandwiched therebetween wherein one of the two surfaces is further defined as an outermost surface of one of the two platen.

8-10. (canceled)

11. The method of claim 1 wherein the fluidic mechanism is further defined as a hydraulic mechanism or a pneumatic mechanism.

12. The method of claim 1 wherein one of the two surfaces is further defined as a top surface, the other of the two surfaces is further defined as a bottom surface, and the fluidic mechanism moves the top surface towards the bottom surface and/or the bottom surface towards the top surface.

13. The method of claim 1 wherein the precursor comprises silicon atoms and is optionally cured by hydrosilylation.

14. The method of claim 13 wherein the precursor comprises:
A. a diorganopolysiloxane having alkenyl groups;
B. a cross-linking agent having silicon-bonded hydrogen atoms; and
C. a hydrosilylation catalyst,
wherein a mole ratio of silicon-bonded hydrogen atoms in the (B) cross-linking agent to alkenyl groups in the (A) diorganopolysiloxane is greater than 1.

15. The method of claim 14 wherein the (A) diorganopolysiloxane is further defined as a polydimethylsiloxane having two terminal alkenyl groups per molecule, and wherein the (B) cross-linking agent is selected from the group of dimethylhydrogen terminated dimethyl siloxanes, dimethyl-methylhydrogen siloxanes that are trimethylsiloxy terminated, and combinations thereof.

16. The method of claim 1 wherein the precursor comprises carbon atoms, is substantially free of compounds including silicon atoms, and optionally comprises at least one of an ethylene-vinyl acetate copolymer, a polyurethane, an ethylene tetrafluoroethylene, a polyvinylfluoride, a polyethylene terephthalate, and combinations thereof.

17. A cell press for forming a photovoltaic cell module comprising a substrate, a photovoltaic cell disposed on the substrate, a tie layer disposed on the photovoltaic cell and formed from a precursor having a viscosity of less than about 1,500 cPs measured at 25° C. before curing, and a superstrate disposed on the tie layer, said cell press having a longitudinal axis and comprising:
A. a first surface configured to support the substrate, photovoltaic cell, tie layer, and superstrate;
B. a second surface disposed opposite said first surface along the longitudinal axis; and
C. a fluidic mechanism for moving one of said first and second surfaces along the longitudinal axis towards said other surface to compress the substrate, photovoltaic cell, tie layer or precursor thereof, and superstrate and form the photovoltaic cell module.

18. The cell press of claim 17 further comprising an inflatable bladder wherein one of said first and second surfaces is further defined as an outermost surface of said inflatable bladder.

19. The cell press of claim 17 further comprising two platen wherein each of said first and second surfaces is further defined as an outermost surface of said two platen.

20. The cell press of claim 17 further comprising two platen wherein each of said first and second surfaces is further defined as an outermost surface of said two platen.

21. The cell press of claim 17 further comprising two platen and an inflatable bladder sandwiched therebetween wherein one of said first and second surfaces is further defined as an outermost surface of one of said two platen.

22. The cell press of claim 17 further comprising an insert for contacting the substrate or superstrate,
wherein said insert has a first outermost surface and a second outermost surface, wherein said first outermost surface is disposed proximal to, and the second outermost surface is disposed distal to, one of said two surfaces of said cell press moveable by said fluidic mechanism,
wherein said first and second outermost surfaces are disposed substantially parallel to each other,
wherein said first outermost surface defines a two-dimensional surface area proximal to said surface of said cell press moveable by said fluidic mechanism and said second outermost surfaces defines a two-dimensional surface area distal to said surface of said cell press moveable by said fluidic mechanism,
wherein said two-dimensional surface area of said second outermost surface is disposed to contact the substrate or superstrate, and
wherein said two-dimensional surface area of said first outermost surface is less than the two-dimensional surface area of said second outermost surface for distributing force to the substrate, photovoltaic cell, tie layer or precursor thereof, and superstrate lateral to the longitudinal axis.

23. The cell press of claim 17 wherein said fluidic mechanism is further defined as a hydraulic mechanism or a pneumatic mechanism.
